(19) United States
(12) Patent Application Publication
(10) Pub. No.: US 2013/0068509 A1
(43) Pub. Date: Mar. 21, 2013

(54) METHOD AND APPARATUS FOR CONNECTING INLAID CHIP INTO PRINTED CIRCUIT BOARD

(71) Applicant: Hong Beom PYEON, Ottawa (CA)

(72) Inventor: Hong Beom PYEON, Ottawa (CA)

(73) Assignee: MOSAID TECHNOLOGIES INCORPORATED, Ottawa (CA)

(21) Appl. No.: 13/621,887

(22) Filed: Sep. 18, 2012

Related U.S. Application Data
(60) Provisional application No. 61/537,206, filed on Sep. 21, 2011.

(51) Int. Cl. H05K 7/20; H05K 1/11; H05K 3/32; H05K 1/00

(52) U.S. Cl. 174/252; 174/250; 174/262; 174/263; 29/832

(57) ABSTRACT

A method and apparatus for mounting microchips 3 into Printed Circuit Boards (PCB) 1 is described. The PCB 1 is provided with a cavity 2 into which the microchip 3 is mounted. Connections 28 are made to signal lines in the PCB 1 and the cavity 2 filled with molding compound 30. In some embodiments one 4 or two 5 inlaid metal layers are thermally connected to microchip 3 to improve thermal conductivity. Thermal panels 8 and 9 or heat sinks 18 and 19 are attached to the inlaid metal layers 4 and 5 to further increase thermal conductivity depending upon the embodiment.

### CROSS REFERENCE TO RELATED APPLICATIONS

This application claims priority from U.S. Provisional Patent Application Ser. No. 61/537,206, entitled “METHOD AND APPARATUS FOR CONNECTING INLAID CHIP INTO PRINTED CIRCUIT BOARD”, filed Sep. 21, 2011, which is incorporated herein by reference in its entirety.

### FIELD OF THE INVENTION

The present invention relates to mounting of semiconductor integrated circuits to printed circuit boards, with greater particularity the invention relates to mounting memory devices to printed circuit boards, and with still greater particularity the invention relates to methods and apparatus for mounting memory devices to PCBs while providing adequate heat dissipation.

### BACKGROUND OF THE INVENTION

The emergence of mobile consumer electronics, such as cellular telephones, laptop computers, Personal Digital Assistants (PDAs), and MP3 players to name but a few, has increased the demand for compact, high performance memory devices. In many ways, the modern development of semiconductor memory devices may be viewed as a process of providing the greatest number of data bits at defined operating speeds using the smallest possible device. In this context, the term “smallest” generally denotes a minimum area occupied by the memory device in a “lateral” X/Y plane, such as a plane defined by the primary surfaces of a printed circuit board (PCB) or module board Conventional construction is shown in FIG. 1.

Not surprisingly, restrictions of the tolerable lateral area occupied by a semiconductor device have motivated micro-chip designers to vertically integrate the data storage capacity of their devices. Thus, for many years now, multiple memory devices that might have been laid out adjacent to one another in a lateral plane have instead been vertically stacked one on top of the other in a Z plane relative to the lateral X/Y plane.

Recent developments in the fabrication of so-called “Through Silicon Vias (TSVs)” have facilitated the trend towards vertically stacked semiconductor memory devices. Most 3-D stacked technologies have focused on only chip-level integration with vertical direction, so far. On PCB (Printed Circuit Board), each individual chip requires space to connect signal pins to PCB nodes electrically and physically. Also, the problem of heat generated by micro-chips has become much worse due to increased power consumption of high capacity micro-chips. Therefore, except for some logic micro-chips, most main semiconductor chips including CPU (Central Processing Unit), GPU (Graphic Processing Unit), and high performance memories (DDR3, DDR4, GDDR5, etc . . . ) demand highly efficient heat sink structures. A heat sink is physically designed to increase the surface area in contact with the cooling fluid surrounding it, such as the air. Approach air velocity, choice of material, fin (or other protrusion) design and surface treatment are some of the design factors which influence the thermal resistance, i.e. thermal performance, of a heat sink. Because of this surface area requirement of heat sinks, the CPU or GPU have bulky heat sinks and need to sufficient space to mount both the microchips and associated heat sinks on PCB. Recently, mobile innovations have been surged as main trend of semiconductor industry so that compact design of the electrical component is mandatory.

In particular mobile products require compact design of PCB and small form factors of each individual component in order to shrink the total size of mobile products. The consumer market still demands at least the performance of main lap-top level from mobile products. Therefore, simply adopting lap-top CPUs and GPUs with big heat sinks is not a viable a solution. System designers have struggled to find the best trade-off between power consumption and performance of system speed determining components, such as CPU, GPU, and main memories like DRAM. Heat sink efficiency is determined by total area of heat sink and thermal characteristics of heat sink itself and chip package material. Main chip components (CPU, GPU, and main memories) should have heat sink fins or panel to spread out heats from them so that the total area of PCB cannot be shrunken as much as system designers want. Additionally, the package itself requires some space to have ball connections as shown in FIG. 1. Real chip size is frequently smaller than the package itself. Of course in actual applications there are several chips mounted to a PCB as illustrated in FIG. 2.

One proposed solution to provide better chip mounting and heat sink placement is Copper Inlay Technology by Ruwel technology as shown in FIG. 3. Copper inlay technology offers an alternative to the prior concepts for direct removal of heat from the circuit board. Thermal vias are arranged in arrays below thermally critical components with the object of transferring heat away from the component by spreading through copper areas on the inner layers or through the board to heatsinks. Unlike normal plated through holes, thermal vias do not have to be electrically insulated from one another and so allow a high hole density. Because the copper in the hole is highly conductive, a maximum number of small holes will produce the lowest thermal resistance.

A typical array of thermal vias has an average thermal conductivity of approx. 30 W/mK. Thermal vias are a cost-effective method for dissipating heat, because the holes are drilled during the standard drilling process. A logical further-development of this technology is to replace the thermal via array by the copper inlay technique, in which a piece of solid copper is pressed and anchored into the full thickness of the circuit board. The copper inlay acts, first, as a soldering surface for power semiconductors and, second, as a highly efficient heat conducting path (source of heat to heatsink) through the circuit board. From that side, the heat can be removed direct to suitable heat sinks using heat-conducting adhesive. A typical value for the thermal conductivity of a copper inlay is 370 W/mK, meaning that it is more than 10 times more efficient than thermal vias. In addition to excellent thermal conductivity, there are also advantages in the component insertion process because the solder paste cannot, as with thermal vias, flow into the holes and the component is soldered over its full contact surface. In addition, this technology is extremely cost-effective and can be fully automated.

However, even this new approach to have compact PCB design with high thermal conductivity does not resolve ultimate problem of form factor issue of package itself. And only one side of heat spreading is allowed as shown in FIG. 3.

Micro-chips are usually covered by a packing compound as final component products. This additional process step demands more test time and cost in to the chip maker. In addition, package size of each of the chips seriously affects total form factor of final electrical products. While thermal conductivity has been improved with new types of ventilation methods and use of a small air fan for each heat generating microchip a penalty is paid in complexity size and power use. More recently the wafer itself has been sold to system manufacturers as final components without packaging by chip maker. In this case, system user can easily determine their own form factor depending on their system requirement and PCB size. There is a demand for an improved method and apparatus for microchip mounting which retains effective heat transfer.

### SUMMARY OF THE INVENTION

The invention provides an improved method and apparatus for microchip mounting which retains effective heat transfer. The invention allows the mounting of a microchip in the interior of a PCB board with the ability to transfer heat from the microchip to the board and outside environment.

This invention does not require packaging processing at the chip manufacturing stage. In contrast to the present packaging technology where all required micro-chips are mounted on the PCB with substantially planar top and bottom surfaces all or some micro-chips which occupy big PCB area and generate operating heat are inlaid into the PCB. The result is that less area is consumed than the current chip mounting on PCB. In addition, both sides of PCB can be provided with a thermal panel or heat sink in order to have increased air flow. In comparison to the single thermal panel or heat sink which used in present PCB. From a system view point, the invention provides compact and versatile system design to achieve small form factor that is a critical factor in the mobile products. This invention also provides for competitive heat spreading using both sides of thermal panel placement on PCB. All chips on PCB do not necessarily need to have this approach. It can be applied only to critical and heat generating chip or chips which require a large PCB area for mounting. Without the necessity of chip packaging, micro-chips incorporated into PCB and signal wirings are superior to packaging methods which are available in semiconductor industry.

Another embodiment allows the attachment of a heat sink to the microchip to further increase heat transfer. A further refinement of this embodiment allows the attachment of heat sinks to both sides of a microchip.

Yet other embodiments substitute thermal panels having high heat conductivity for one or several heat sinks.

A further embodiment of the invention allows passage of signal lines under and around a microchip embedded in a PCB board.

Yet another embodiment allows the addition of a bump pad to the invention to provide enhanced routing flexibility.

### BRIEF DESCRIPTION OF THE DRAWINGS

Features and advantages of the present invention will become apparent from the following detailed description, taken in combination with the appended drawings for clarity. In the figures only a single microchip is shown but it is appreciated that the actual number of microchips on a PCB board will far exceed one.

FIG. 1 is a cross sectional drawing of conventional microchip placement on a PCB;

FIG. 2 is a top plan view of multiple microchip placement on a PCB;

FIG. 3 is a cross sectional drawing of an alternative microchip mounting to a PCB;

FIG. 4 is a cross sectional drawing of a first embodiment of the invention;

FIG. 5 is cross sectional drawing of a second embodiment of the invention;

FIG. 6 is a detailed cross sectional drawing of the FIG. 3 embodiment

FIG. 7 is a detailed cross sectional drawing of the FIG. 4 embodiment;

FIG. 8 is a detailed cross sectional drawing of a third embodiment of the invention;

FIG. 9 is a detailed cross sectional drawing of a fourth embodiment of the invention;

FIG. 10 is a detailed cross sectional drawing of a fifth embodiment of the invention;

FIG. 11 is a detailed cross sectional drawing of a sixth embodiment of the invention;

FIG. 12 is a detailed cross sectional drawing of a seventh embodiment of the invention;

FIG. 13 is a detailed cross sectional drawing of a eighth embodiment of the invention.

FIG. 14 is a detailed cross sectional drawing of a ninth embodiment of the invention.

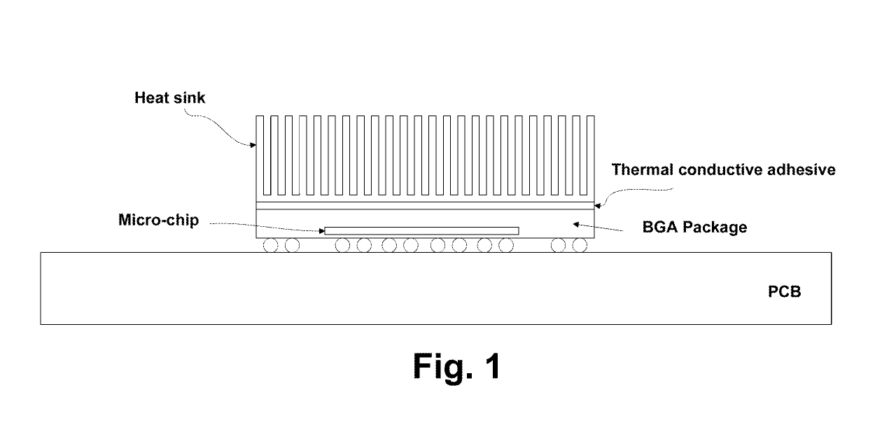

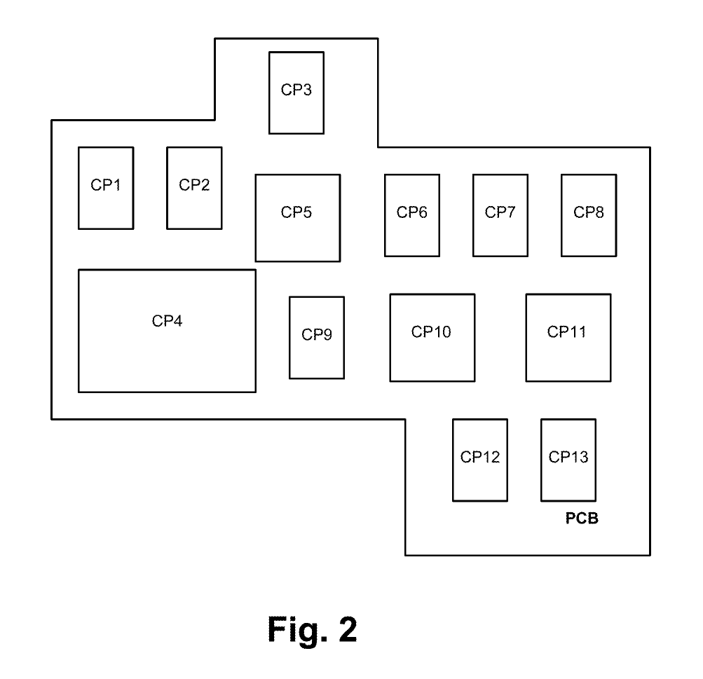

### DETAILED DESCRIPTION OF VARIOUS EMBODIMENTS

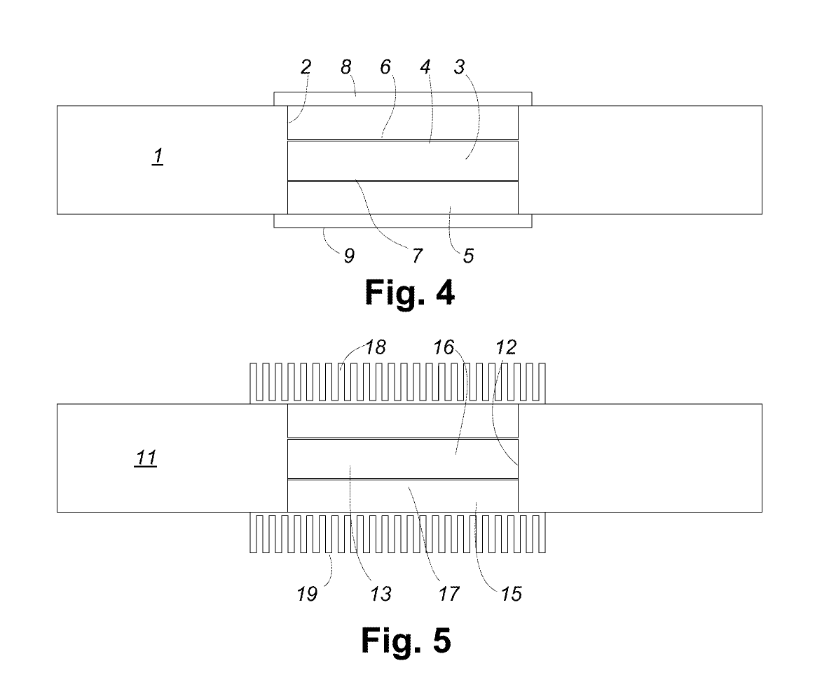

FIG. 4 is a sectional drawing of a first embodiment of the invention. The PCB 1 with substantially planar top and bottom surfaces includes a cavity 2 containing a microchip 3. Cavity 2 may be created by carving out a recess in PCB 1 or present in the original stamping of PCB 1. An inlaid metal layer 4 is placed on the top 6 surface and a similar inlaid metal layer 5 is in contact with the bottom surface 7 of microchip 3. Inlaid metal layers 4 and 5 are small pieces of a thermally conductive metal such as copper, aluminum and silver. While two thermal panels are shown some applications may have one or even none. A top thermal panel 8 is in contact with inlaid metal layer 4. A bottom thermal panel 9 may be provided in contact with inlaid metal layer 5. In operation heat from microchip 3 is transferred through inlaid metal layers 5 and 6 to thermal panels 8 and 9, where it may be dissipated.

FIG. 5 is a sectional drawing of a second embodiment of the invention. This embodiment is similar to that of FIG. 4 except that heat sinks are used rather than thermal panels. While two heat sinks are shown some applications may have one or even none. The PCB 11 with substantially planar top and bottom surfaces includes a cavity 12 containing a microchip 13. An inlaid metal layer 14 is placed on the top 16 surface and a similar inlaid metal layer 15 is in contact with the bottom surface 17 of microchip 13. A top heat sink 18 is in contact with inlaid metal layer 14. A bottom heat sink 19 may be provided in contact with inlaid metal layer 15. In operation heat from microchip 13 is transferred through inlaid metal layers 15 and 16 to heat sinks 18 and 19, where it may be dissipated.

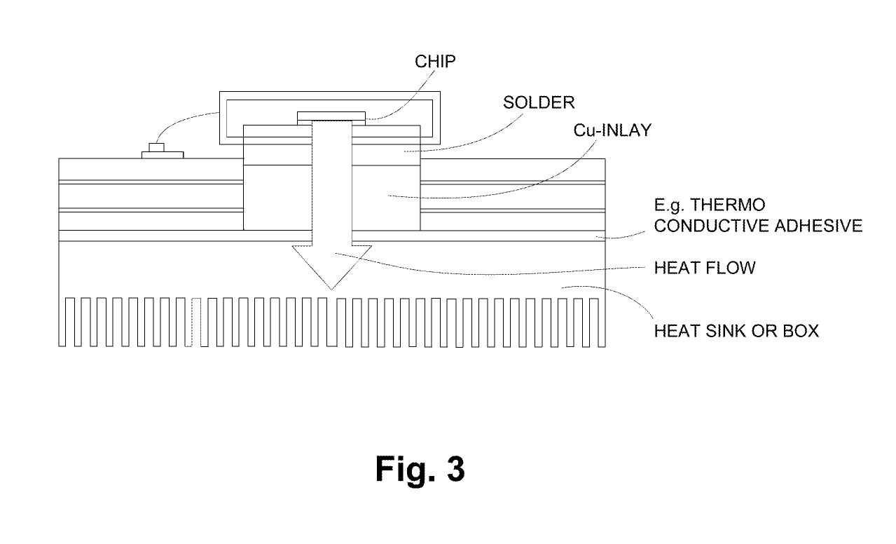

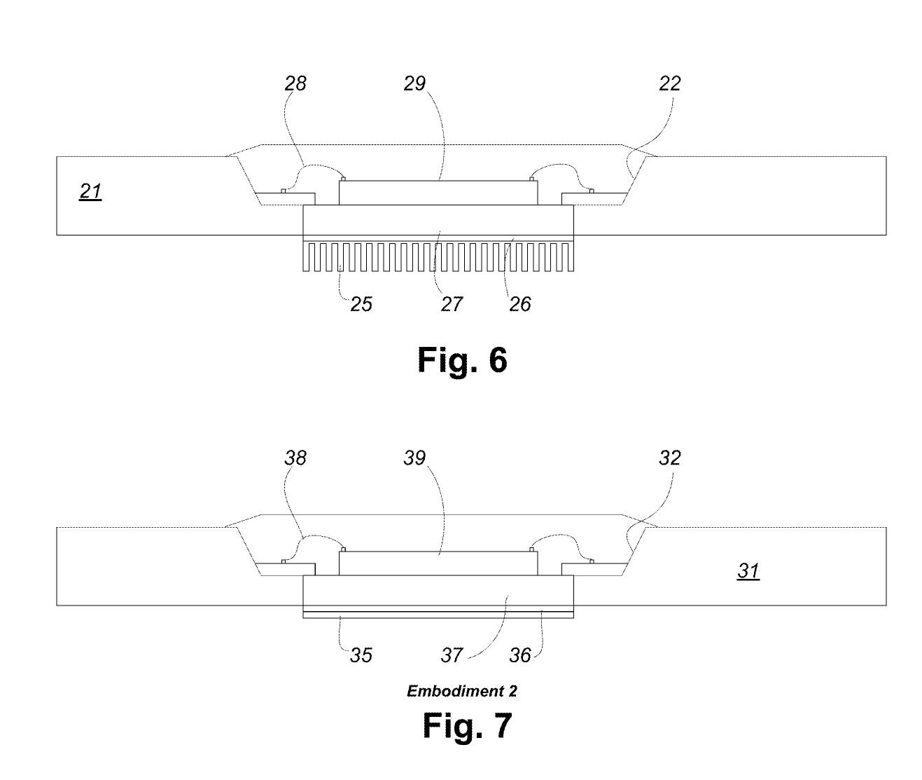

FIG. 6 is a detailed cross sectional drawing of the FIG. 3 embodiment with a single heat sink. Microchip 23 is emplaced in cavity 22. Inlaid metal layer 24 is in thermal contact with the bottom surface 27 of microchip 23. A single heat sink 25 is connected to inlaid metal layer 24 by use of a thermally conductive adhesive 26. The signal connection from a pad on the top surface 29 of micro-chip 23 to a PCB signal contact point is performed with bonding wire 29. The remainder of cavity 22 is filled with a molding compound 30. Any other types of connections between the micro-chip and PCB signal contact point are included in this proposed embodiment if a micro-chip 23 is inlaid as shown in FIG. 6. Inlaid metal layer 24 ensures much better thermal conductivity compared to the presently available heat sink methods.

FIG. 7 is a detailed cross sectional drawing of the FIG. 4 embodiment with a single thermal panel 35 rather than a heat sink. Thermal panel 35 has higher thermal conductivity than a heat sink. By use of this structure a system designer can have a very thin PCB which is useful in mobile products such as phones. Unlike chip mounting on a PCB as being used in conventional system board design the form factor is determined only by chip size and bonding wire 38 distance between chip pad and PCB signal contact point. Microchip 33 is emplaced in cavity 32. Inlaid metal layer 34 is in thermal contact with the bottom surface 37 of microchip 33. A single thermal panel 35 is connected to inlaid metal layer 34 by use of a thermally conductive adhesive 36. The signal connection from a pad on the top surface 39 of micro-chip 33 to a PCB signal contact point is performed with bonding wire 39. The remainder of cavity 32 is filled with a molding compound 40.

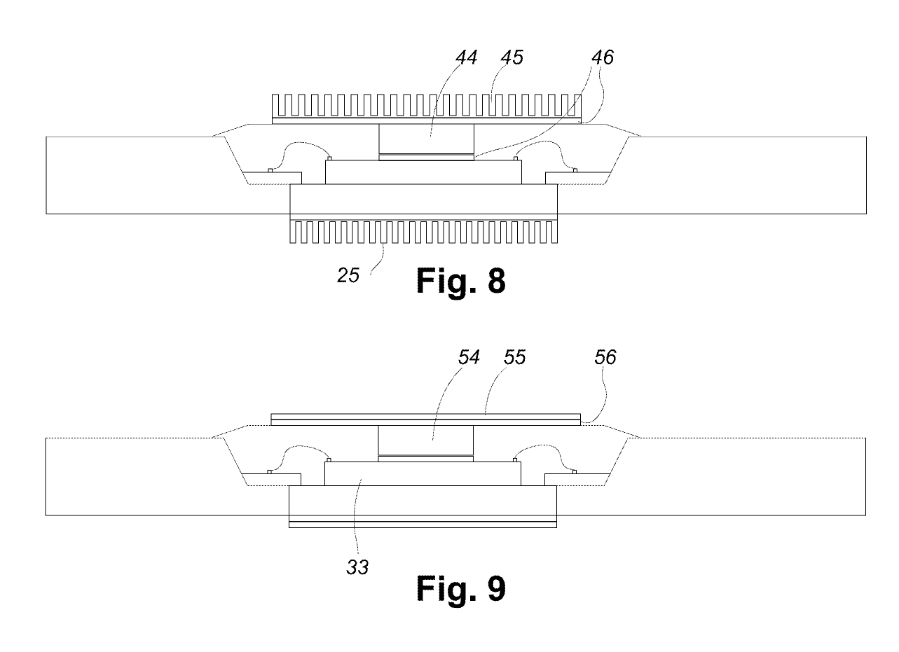

FIG. 8 is a detailed cross sectional drawing of the FIG. 5 embodiment of the invention with double heat sinks 25 and 45. This embodiment is similar to FIG. 6 with additional components 44-46. This configuration is particularly useful in the case when micro-chip 33 generates higher heat so that using by heat sinks 25 and 45 on each side quick heat spreading can be achieved. Compared to FIG. 4 and FIG. 7, the PCB thickness and heat sink height determines form factor of system board design. But, still the total size of PCB including heat sink height is smaller than the presently available chip mounting ways on PCB. An additional metal inlay layer 44 is bonded to the top surface of microchip 33 and second heat sink 45 by the use of a thermally conductive adhesive 46.

FIG. 9 is a detailed cross sectional drawing of the FIG. 4 embodiment of the invention with double thermal panels 35 and 55. This embodiment is similar to FIG. 7 with additional components 54-56. This configuration is particularly useful in the case when micro-chip 33 generates higher heat so that by using thermal panels 35 and 55 on two sides quick heat spreading can be achieved. Compared to FIG. 4 and FIG. 7, the height is smaller and the heat spreading efficiency is even greater. An additional metal inlay layer 54 is bonded to the top surface of microchip 33 and thermal panel 55 by the use of a thermally conductive adhesive 56.

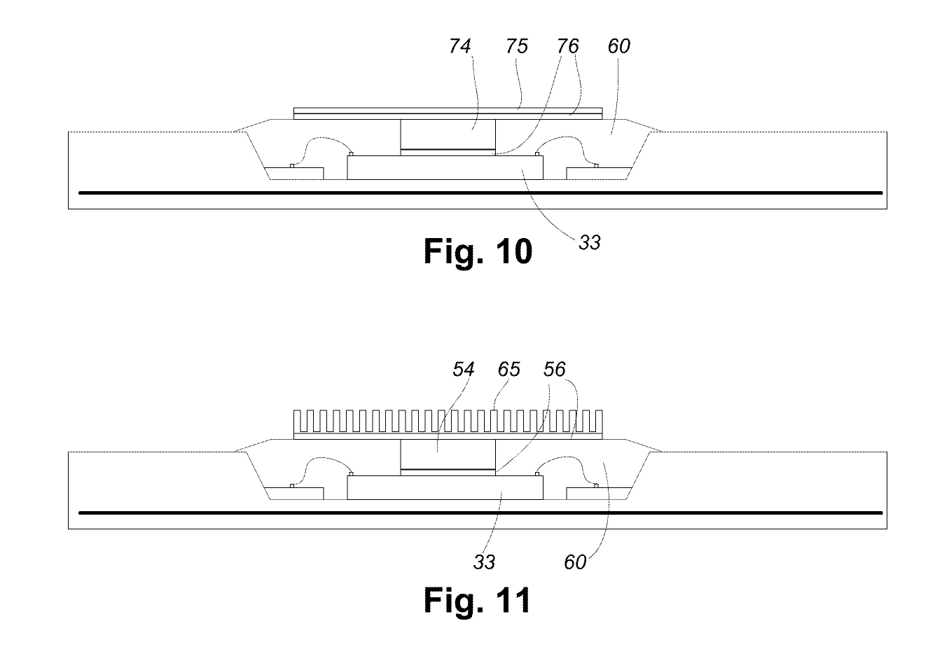

FIG. 10 is a detailed cross sectional drawing of a fifth embodiment of the invention. FIG. 10 shows how the construction allows a way to have a signal line 77 passing under a micro-chip. To have this structure, a heat sink 65 should be placed over the molding compound side of microchip 33. A metal inlay layer 54 is bonded to the top surface of microchip 33 and heat sink 65 by the use of a thermally conductive adhesive 56.

FIG. 11 is a detailed cross sectional drawing of a sixth embodiment of the invention. FIG. 11 shows how the construction allows a way to have a signal line 77 passing under a micro-chip. To have this structure, a thermal panel 75 should be placed over the molding compound side of microchip 33. A metal inlay layer 74 is bonded to the top surface of microchip 33 and thermal panel 75 by the use of a thermally conductive adhesive 76.

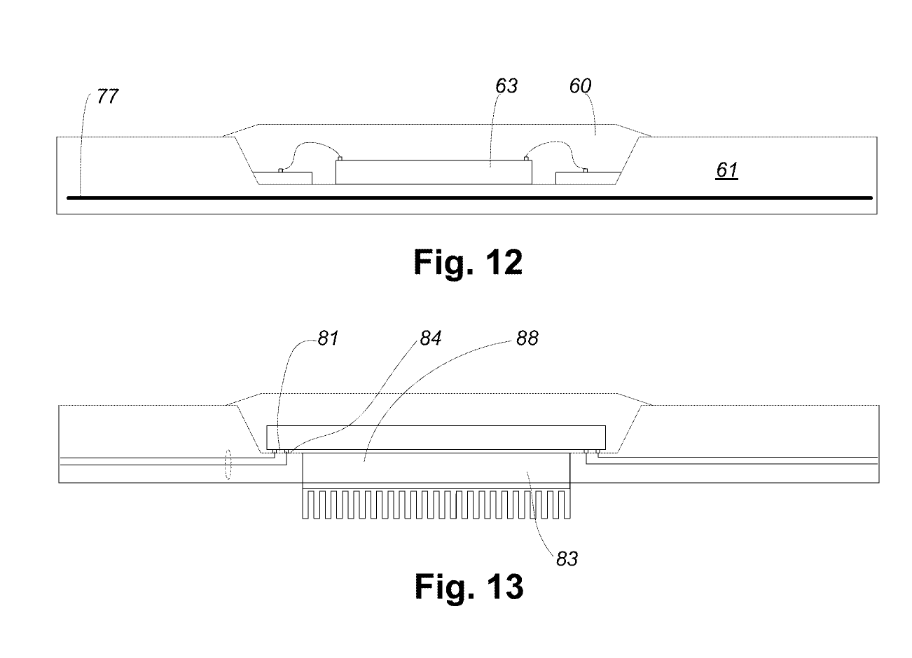

FIG. 12 is a detailed cross section of a seventh embodiment. This construction is useful in situations where neither heat sink nor thermal panels are needed in PCB design. In FIG. 12 signal lines 77 of PCB 61 can be by-passed under microchip 63. This method is applicable to a microchip such as a logic chip with less heat generation and which does not affect system reliability and performance. Using this method improved routing placement on PCB along with inlaid chip placement can be obtained.

FIG. 13 is a detailed cross section of an eighth embodiment using solder ball connections 84. FIG. 13 shows the case bump pad 81 of a micro-chip 83. In case of edge bump pad placement of a micro-chip, any direction of heat sink or thermal panel placement (double or single) is allowed. In FIG. 13 the inlaid metal layer 88 is below microchip 83 and connected to a heat sink by a thermally conductive adhesive 87. A thermal panel can be substituted for heat sink 86 as shown above.

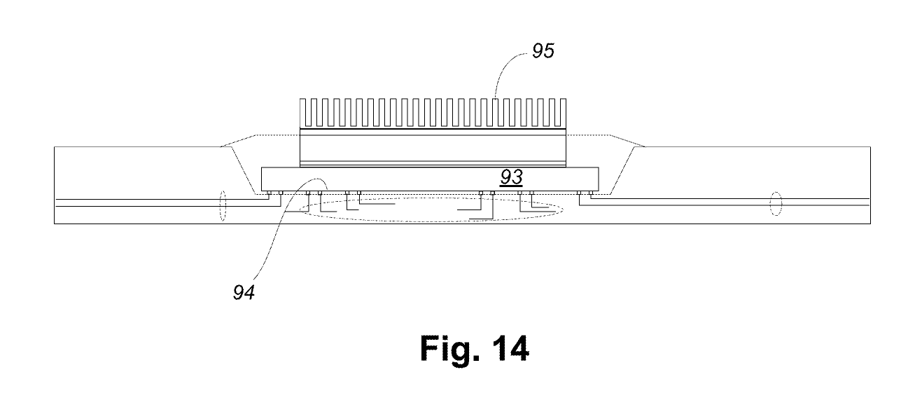

FIG. 14 is a detailed cross section of a ninth embodiment using solder ball connections 94. This embodiment improves upon FIG. 13 as it allows use of a micro-chip 93 having bump pads on all locations. It is limited to use of such as is required to have a single side heat sink 95 or thermal panel. FIG. 14 has better routing flexibility on PCB design.

The embodiments shown are exemplary only the invention being defined by the attached claims only.

1. A Printed Circuit Board (PCB) comprising:
a substantially planar top surface; and
a substantially planar bottom surface; and
an electrically insulating material extending between said top and said bottom surface;
a cavity in said electrically insulating material configured to accept a microchip.

2. A Printed Circuit Board (PCB) as in claim 1, further comprising: a first inlaid metal layer in said cavity configured to be in thermal connection with any microchip in said cavity.

3. A Printed Circuit Board (PCB) as in claim 2, wherein said first inlaid metal layer is configured for attachment to a thermal panel.

4. A Printed Circuit Board (PCB) as in claim 2, wherein said first inlaid metal layer is configured for attachment to heat sink.

5. A Printed Circuit Board (PCB) as in claim 2, further comprising a second inlaid metal layer in said cavity configured to be in thermal connection with the side opposite that of said first inlaid metal layer of any microchip in said cavity.

6. A Printed Circuit Board (PCB) as in claim 5, wherein said second inlaid metal layer is configured for attachment to a thermal panel.

7. A Printed Circuit Board (PCB) as in claim 5, wherein said second inlaid metal layer is configured for attachment to a heat sink.

8. A Printed Circuit Board (PCB) as in claim 1, further comprising: a molding composition filling at least a portion of said cavity.

9. A Printed Circuit Board (PCB) as in claim 1, further comprising: at least one signal line passing under said cavity.

10. A Printed Circuit Board (PCB) as in claim 1, further comprising: an electrical connection configured to connect to any microchip in said cavity.

11. A Printed Circuit Board (PCB) as in claim 11, wherein said electrical connection includes a pad configured to attach to a bonding wire.

12. A Printed Circuit Board (PCB) as in claim 11, wherein said electrical connection further includes a bump pad configured to attach to a solder ball.

13. A method for attaching microchips to a printed circuit board comprising the steps of; providing a cavity in said printed circuit board, and, placing a microchip in the cavity provided, and, further providing electrical connections to the microchip.

14. A method for attaching microchips to a printed circuit board as in claim 13 further comprising the step of providing a path for heat to escape the microchip by use of a metal inlay.

15. A method for attaching microchips to a printed circuit board as in claim 15 further comprising the step of providing a heat radiator connected to the metal inlay.

16. A method for attaching microchips to a printed circuit board as in claim 15 wherein the heat radiator is a heat sink

17. A method for attaching microchips to a printed circuit board as in claim 15 wherein the heat radiator is a thermal panel

18. A method for attaching microchips to a printed circuit board as in claim 14 further comprising the step of further providing a second path for heat to escape the microchip positioned on the side of the microchip opposite the first heat escape path.
